(19) United States
(12) Patent Application Publication
(10) Pub. No.: US 2026/0033303 A1
(43) Pub. Date: Jan. 29, 2026

(54) WAFER STACKING METHOD AND WAFER STACK STRUCTURE

(71) Applicant: WUHAN XINXIN SEMICONDUCTOR MANUFACTURING CO., LTD., Wuhan (CN)

(72) Inventors: Hu YANG, Wuhan (CN); Yu ZHOU, Wuhan (CN); Sheng HU, Wuhan (CN)

(21) Appl. No.: 19/264,167

(22) Filed: Jul. 9, 2025

(30) Foreign Application Priority Data
Jul. 25, 2024 (CN) 202411009352.3

(51) Int. Cl. H01L 23/00; H01L 21/768

(52) U.S. Cl. CPC H01L 24/80; H01L 21/76898; H01L 24/03; H01L 24/08; H01L 2224/03019; H01L 2224/08145; H01L 2224/80895; H01L 2224/80896

(57) ABSTRACT

A wafer stacking method and a wafer stack structure are disclosed. In the wafer stacking method, first and second wafer structures are formed and then stacked and bonded. Prior to the stacking and bonding of the first and second wafer structures, metal pad is pre-formed on one side of the first wafer structure. In this way, it is unnecessary to form the metal pad after the first and second wafer structures are stacked and bonded, avoiding wafer warpage distortion, which may occur in high-temperature treatment involved in the formation of the metal pad. Thus, the risks of layer and/or film fracture and alarming of processing equipment in subsequent processes are reduced, and more wafers are allowed to be stacked by wafer-level stacking. The wafer stack structure is obtainable according to the wafer stacking method.

### CROSS-REFERENCE TO RELATED APPLICATION

This application claims the priority of Chinese patent application number 202411009352.3, filed on Jul. 25, 2024 and entitled “WAFER STACKING METHOD AND WAFER STACK STRUCTURE”, the entire contents of which are incorporated herein by reference.

### TECHNICAL FIELD

The present invention relates to the field of semiconductor technology and, in particular, to a wafer stacking method and a wafer stack structure.

### BACKGROUND

With the advancement of semiconductor technology and increasing market demand for higher performance in electronic devices, research on applying wafer-level stacking technology to vertically interconnect multiple dies has been growing rapidly. By vertically interconnecting multiple dies, the number of transistors per unit area can be multiplied, and the degree of integration has been increased significantly. Additionally, this approach shortens total wiring length, improves interconnection speed, reduces response time, and lowers power consumption. Moreover, vertically interconnected dies can be heterogeneous, enabling the realization of complex system functionalities.

Wafer-level stacking involves stacking multiple wafers in the thickness direction in a manner allowing the establishment of vertical interconnections. However, as the number of stacked wafers increases, the warpage issue of the resulting wafer stack structure becomes more severe, elevating risks of layer and/or film fracture and alarming of semiconductor equipment handling such structures.

### SUMMARY OF THE INVENTION

In order to mitigate the warpage problem of wafer stack structure, the present invention provides a wafer stacking method and a wafer stack structure.

In one aspect, the present invention provides a wafer stacking method comprising:
forming a first wafer structure comprising at least one first wafer, wherein a side of the first wafer structure is pre-formed with at least one metal pad;
forming a second wafer structure comprising at least one second wafer;
stacking and bonding the first and second wafer structure wherein the second wafer structure is bonded to a side of the first wafer structure that is away from the metal pad; and
forming at least one opening on a side of the first wafer structure, wherein the metal pad is exposed from the opening.

Optionally, forming the first wafer structure may comprise:
taking one of the at least one first wafer in the first wafer structure as a top wafer, wherein the top wafer comprises at least one first interconnect structure formed on a first substrate and a dielectric layer formed on the first interconnect structure;
forming at least one through hole in the dielectric layer, wherein the through hole exposes a metal layer of the first interconnect structure; and
depositing a metal material into the through holes and onto a surface of the dielectric layer, and patterning the metal material, thereby forming a top metal layer connected to the first interconnect structure, wherein the top metal layer contains the metal pad s.

Optionally, forming the first wafer structure may further comprise:
after the top metal layer is formed, forming a first oxide layer and a nitride layer on a surface of the top wafer;
forming a second oxide layer covering the nitride layer, wherein an upper surface of the second oxide layer is higher than a surface of the nitride layer;
performing a planarization process using the nitride layer as a stop layer; and
forming a third oxide layer covering surfaces of exposed surface portions of the second oxide layer and the nitride layer, wherein the first oxide layer, the nitride layer and the second oxide layer make up a protective layer.

Optionally, the first wafer structure may comprise at least two first wafers which are stacked and bonded together. Alternatively or additionally, the second wafer structure may comprise at least two second wafers which are stacked and bonded together.

Optionally, forming the first wafer structure may comprise:
providing the at least two first wafers, wherein one of the at least two first wafers is a top wafer on which the metal pad is to be formed;
forming a top metal layer and a protective layer covering the top metal layer on the top wafer, wherein the top metal layer contains the metal pad;
bonding the top wafer to a first carrier substrate through the protective layer; and
successively stacking the other first wafer(s) on a side of the top wafer away from the first carrier substrate.

Optionally, forming the first wafer structure may comprise:
providing the at least two first wafers, wherein one of the at least two first wafers isa top wafer on which the metal pad is to be formed;
bonding the top wafer to a second carrier substrate;
successively stacking the other first wafer(s) on a side of the top wafer away from the second carrier substrate;
removing the second carrier substrate;
forming a top metal layer and a protective layer on a side of the top wafer away from the other first wafer(s), wherein the top metal layer contains the metal pad; and
bonding the top wafer to a first carrier substrate through the protective layer.

Optionally, stacking and bonding the first and second wafer structure may comprise:
thinning a substrate of a first wafer in the first wafer structure on a side away from the first carrier substrate, forming through-silicon vias (TSVs) extending through the first wafer using a TSV process and bond pads connected to the TSVs;
forming bond pads on a surface of the second wafer structure, wherein the bond pad is connected to interconnect structure in the second wafer; and
bonding surface of the first wafer structure with the bond pad being formed thereon to surface of the second wafer structure with the bond pad being formed thereon.

In another aspect, the present invention provides a wafer stack structure comprising a first wafer structure and a second wafer structure which are stacked and bonded together, the first wafer structure comprising at least one first wafer, the second wafer structure comprising at least one second wafer, wherein at least one metal pad and a protective layer covering the at least one metal pad are provided on a side of the first wafer structure away from the second wafer structure, wherein the metal pad is exposed from an opening in the protective layer, and wherein a surface of the protective layer away from the second wafer structure is within a single plane.

Optionally, the first wafer structure may comprise a top wafer comprising at least one first interconnect structure formed on a first substrate, and a dielectric layer and a top metal layer formed on the first interconnect structures, wherein the dielectric layer is provided with at least one through hole, wherein the top metal layer extends through the through hole in the dielectric layer to connect with metal layer of the first interconnect structure, the top metal layer containing the metal pad.

Optionally, the protective layer may comprise:
a first oxide layer formed on surfaces of the dielectric layer and the top metal layer, wherein the metal pad is exposed from the first oxide layer;
a nitride layer formed on a surface of the first oxide layer; and
a second oxide layer formed on the nitride layer, wherein a top surface of the second oxide layer is flush with a top surface of the nitride layer.

Optionally, the first wafer structure may comprise at least two first wafers which are stacked and bonded together. Alternatively or additionally, the second wafer structure may comprise at least two second wafers which are stacked and bonded together.

In the wafer stacking method of the present invention, the metal pad is pre-formed on one side of the first wafer structure before the first and second wafer structures are stacked and bonded. In this way, it is unnecessary to form the metal pad after the first and second wafer structures are stacked and bonded, avoiding wafer warpage distortion, which may occur in high-temperature treatment involved in the formation of the metal pad. Moreover, more wafers are allowed to be stacked by wafer-level stacking.

In the wafer stack structure of the present invention, the first and second wafer structures are stacked and bonded, wherein the metal pad and the protective layer covering the at least one metal pad are formed on the side of the first wafer structure away from the second wafer structure. The metal pad is exposed from the opening in the protective layer, and the surface of the protective layer away from the second wafer structure is within a single plane. The metal pad and protective layer can be formed before the first and second wafer structures are stacked and bonded, avoiding the wafer stack structure from undergoing high-temperature treatment involved in the formation of the metal pad or the protective layer, which may cause serious wafer warpage distortion. Moreover, more wafers are allowed to be stacked by wafer-level stacking.

### BRIEF DESCRIPTION OF THE DRAWINGS

FIG. 1 shows a schematic flowchart of a wafer stacking method according to embodiments of the present invention.

FIGS. 2A to 2K show schematic cross-sectional views of structures resulting from steps in a wafer stacking method according to an embodiment of the present invention.

### DETAILED DESCRIPTION

Wafer stacking method and wafer stack structure according to particular embodiments of the present invention will be described in detail below with reference to the accompanying drawings. From the following description, advantages and features of the present invention will be more apparent. Note that the figure is provided in a very simplified form not necessarily drawn to exact scale for the only purpose of helping to explain the disclosed embodiments in a more convenient and clearer way.

In wafer-level stacking technology, as the number of stacked wafers progressively increases, the quantity and volume of metal layers within the resulting wafer stack structure grow correspondingly. Such a wafer stack structure, when subjected to high-temperature treatment, will suffer from more serious warpage, which not only tends to fracture layers or films in the wafers, but also affects subsequent processing of the wafer stack structure. For example, researchers have found that chucks of many types of processing equipment could not stably hold a wafer stack structure when the warpage exceeds a certain value, and it triggers tool alarm and disrupts normal operation. Therefore, in order to ensure good performance of a wafer stack structure and facilitate its subsequent processing, in conventional wafer-level stacking techniques, no more than 5 wafers are usually stacked.

In embodiments of the present invention, a wafer stacking method is provided, before a first wafer structure is bonded to a second wafer structure, a metal pad is pre-formed on one side of the first wafer structure. Moreover, the second wafer structure is stacked on and bonded to the side of the first wafer structure away from the metal pad. After the stacking and bonding, openings are formed in the side of the first wafer structure, exposing the metal pad. In this way, after the first and second wafer structures are stacked and bonded, it is unnecessary to subject wafer stack structure to any high-temperature treatment for forming metal pad, which may cause wafer warpage distortion. Thus, the risks of layer and/or film fracture and alarming of processing equipment are reduced, and more wafers can be stacked using wafer-level stacking.

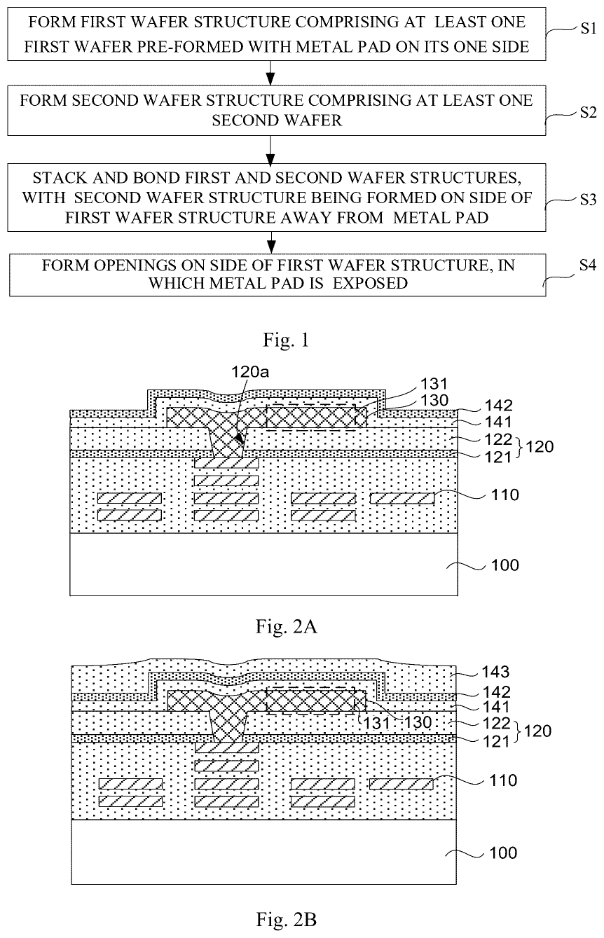

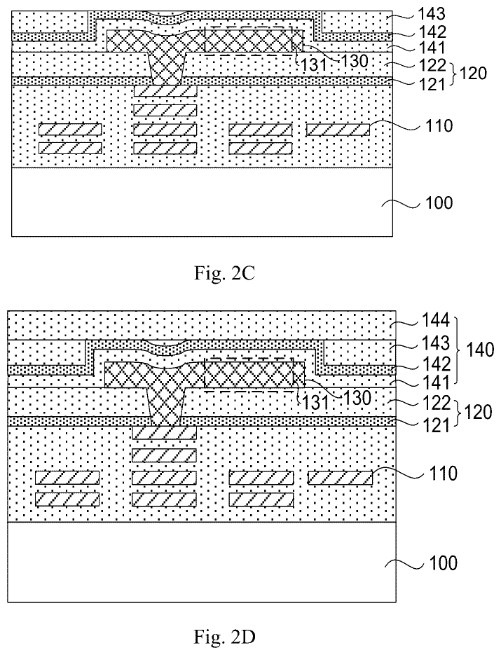

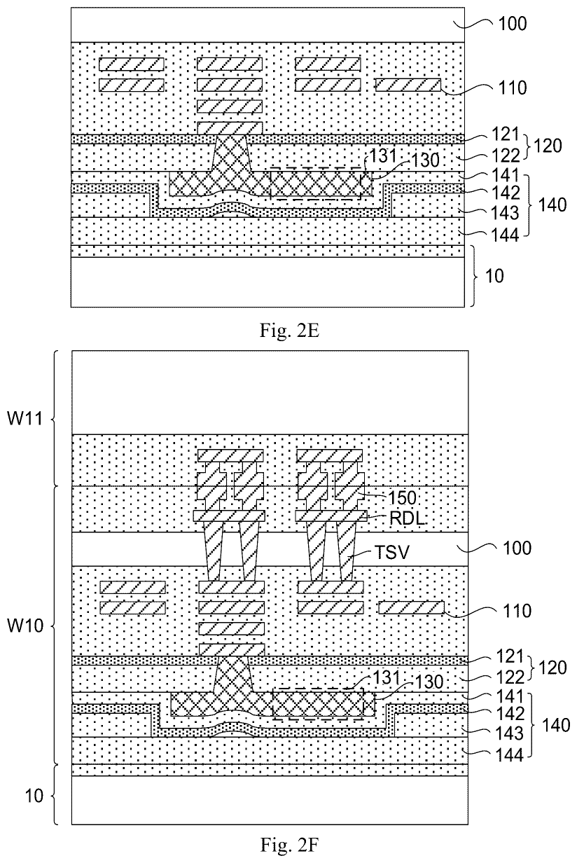

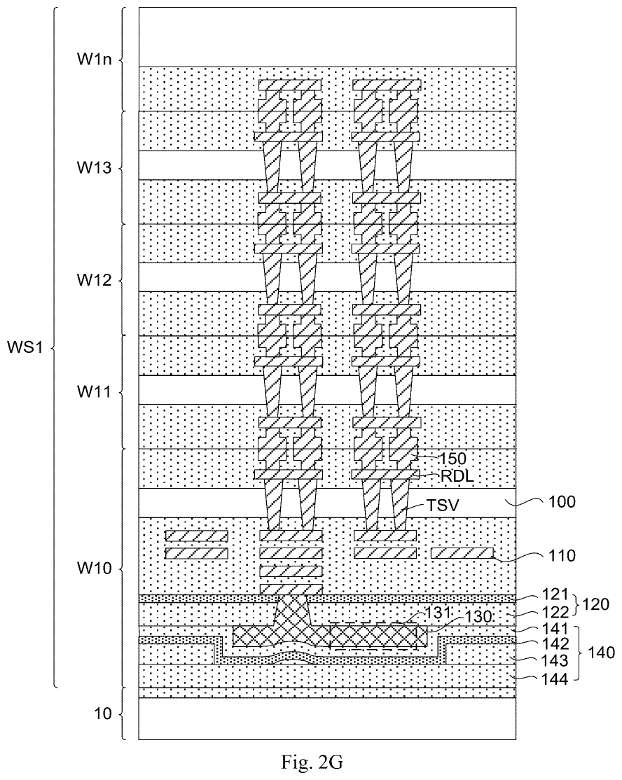

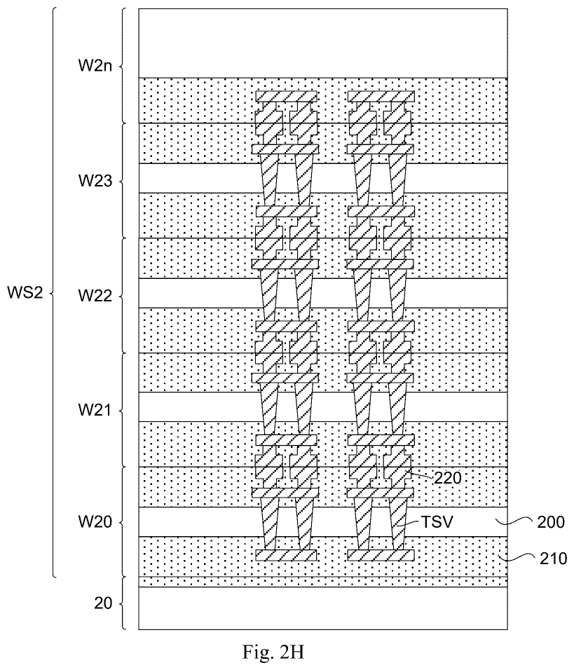

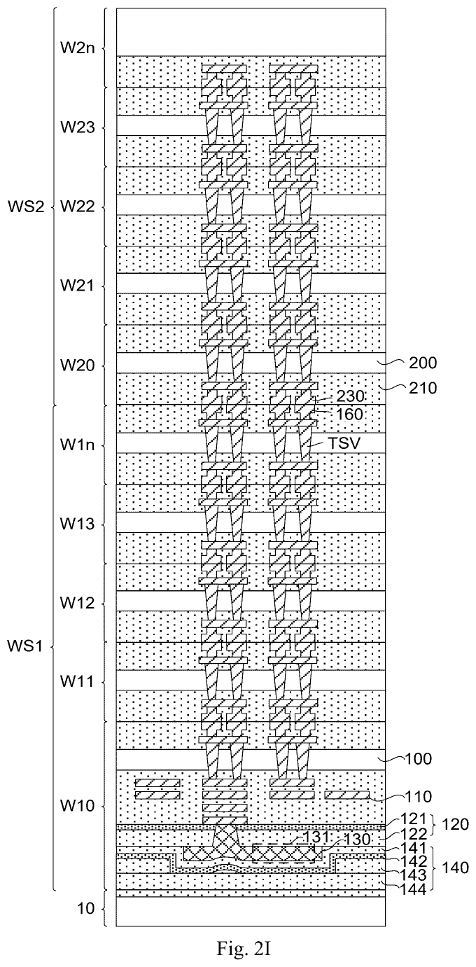

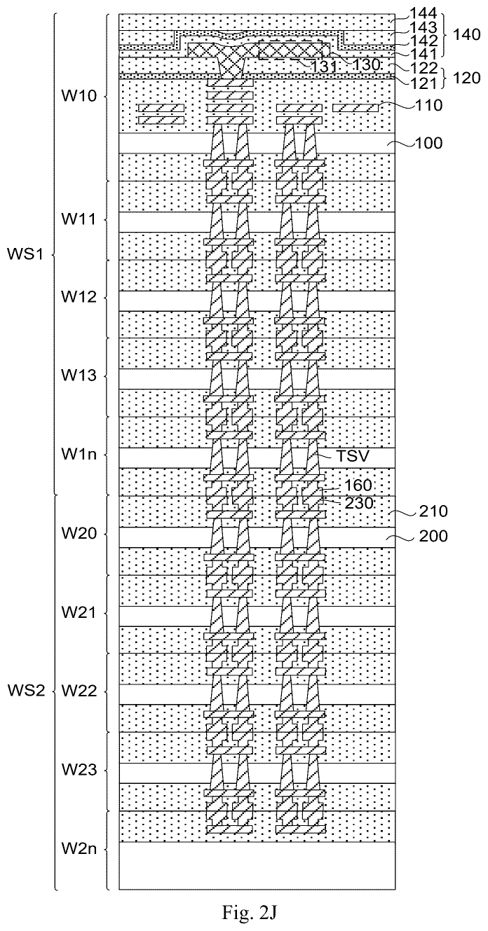

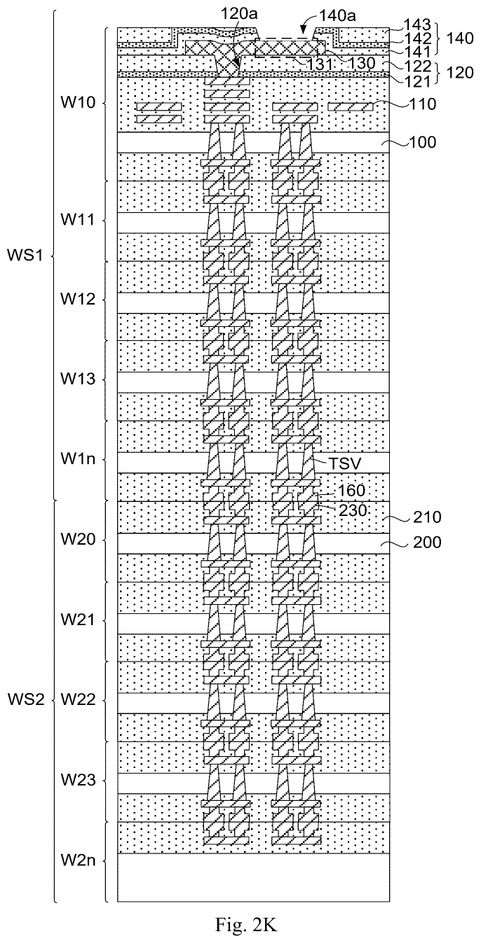

The wafer stacking method of these embodiments of the present invention are further described below with reference to FIGS. 1 and 2A to 2K.

Referring to FIG. 1, in a wafer stacking method according to an embodiment of the present invention, a first wafer structure is formed in step S1, the first wafer structure includes at least one first wafer. Metal pad is pre-formed on one side of the first wafer structure.

Each first wafer in the first wafer structure may include electronic components fabricated using semiconductor processes. The first wafer has a front side with electronic components formed thereon and a backside opposite to the front side. As an example, the at least one first wafer in the first wafer structure may include a logic wafer and/or a memory wafer. The memory wafer may include memory cells, such as non-volatile memory cells or volatile memory cells. Examples of the non-volatile memory cells may include NOR flash memory cells, NAND flash memory cells, ferroelectric memory cells and phase change memory cells. Examples of the volatile memory cells may include DRAM cells and SRAM cells. The logic wafer may include active devices (e.g., MOS transistor) and passive devices. As an example, among the at least one first wafer in the first wafer structure, the first wafer with metal pad formed thereon is a logic wafer.

The first wafer structure may include one, two or more first wafers. When the first wafer structure includes a single first wafer, in step S1, the first wafer is acquired and the metal pad is formed on its one side.

For ease of illustration, in the first wafer structure, the first wafer pre-formed with the metal pad is referred to hereinafter as a “top wafer”. Referring to FIG. 2A, the top wafer may include first interconnect structures 110 formed above a first substrate 100 (which may be formed of silicon or a different material) and a dielectric layer 120 formed above the first interconnect structures 110. For example, the dielectric layer 120 may include a silicon nitride layer 121 and a silicon oxide layer 122 stacked on the first interconnect structures 110. The metal pad may be formed on one side of the top wafer, as described below.

At first, through holes 120a are formed in the dielectric layer 120, exposing metal layer of the first interconnect structure 110.

Subsequently, a metal material (e.g., aluminum or another suitable material) is deposited into the through holes 120a and onto a surface of the dielectric layer 120 and patterned, forming a top metal layer 130 connected to the first interconnect structure 110. The top metal layer 130 may have a thickness, for example, in the range of 8 kÅ to 30 kÅ. The top metal layer 130 includes the metal pad 131. For example, the metal pad 131 may be connected to the first interconnect structure 110 by metal wire in the top metal layer 130, which extend through the through hole 120a.

In order to provide protection to the metal pad 131 and facilitate subsequent bonding of the top wafer to a first carrier substrate, after the metal pad 131 is formed, a protective layer may be additionally formed on the metal pad 131. In particular, this may be accomplished as described below.

First of all, as shown in FIG. 2A, a first oxide layer 141 (e.g., silicon oxide) and a nitride layer 142 (e.g., silicon nitride) are stacked on surfaces of the dielectric layer 120 and the top metal layer 130.

Next, as shown in FIG. 2B, a second oxide layer 143 is formed over the nitride layer 142, a top surface of the second oxide layer 143 is above the nitride layer 142. For example, the second oxide layer 143 may be a silicon oxide layer having a thickness, for example, in the range of 30 kÅ to 60 kÅ. Since the second oxide layer 143 is deposited on a non-flat surface, top surface of the second oxide layer 143 is non-flat.

Afterwards, referring to FIG. 2C, a planarization (e.g., chemical mechanical polishing (CMP)) process is carried out, with the nitride layer 142 serving as a stop layer. After the planarization process is completed, the remaining portion of the second oxide layer 143 covers the surface of lower portions of the nitride layer 142 and is flush with top surfaces of exposed portions of the nitride layer 142.

Referring to FIG. 2D, a third oxide layer 144 is then formed on the exposed portions of the second oxide layer 143 and the nitride layer 142. Since the third oxide layer 144 is deposited on a flat surface, its top surface is flat. For example, the third oxide layer 144 may be a silicon oxide layer having a thickness, for example, in the range of 5 kÅ to 15 kÅ. Thus, the first oxide layer 141, the nitride layer 142, the second oxide layer 143 and the third oxide layer 144 above the first substrate 100 make up a protective layer 140.

When the first wafer structure includes at least two first wafers, in step S1, the metal pad may be first formed on one side of one first wafer, and another first wafer(s) may be then stacked on the other side of said first wafer. In particular, this may be accomplished as described below.

At first, the at least two first wafers are provided, one of the first wafers is the top wafer, on which the metal pad is to be formed.

Next, referring to FIG. 2A to 2D, a top metal layer 130 and a protective layer 140 covering the top metal layer 130 are formed on the top wafer. The top metal layer 130 includes the metal pad 131. The top metal layer 130 and the protective layer 140 may be formed in the same way as described above.

Subsequently, as shown in FIG. 2E, the top wafer W10 is bonded to a first carrier substrate 10 through the protective layer 140, in particular, the top wafer W10 is bonded to a first carrier substrate 10 through the third oxide layer 144 (e.g., adhesively, or otherwise temporarily).

Afterwards, the other first wafer(s) is/are successively stacked on the side of the top wafer away from the first carrier substrate 10.

Referring to FIG. 2F, prior to the successive stacking of the other first wafer(s) on the side of the top wafer (i.e., the first wafer W10) away from the first carrier substrate 10, the first substrate 100 in the top wafer W10 may be thinned from the backside, and a through-silicon via (TSV) process may be then performed on the backside of the top wafer to form TSVs extending through the first substrate 100 and connected to the first interconnect structure 110. Bond pads 150 connected to the respective TSVs are then formed on the backside of the top wafer W10. If required, at least one rewiring layer (RDL) may be additionally formed between the TSVs and the respective bond pads. The RDL may be isolated from the first substrate 100 and the bond pads 150 by a dielectric material while being connected to the bond pads 150 by metal vias formed in the dielectric material. It should be noted that while several TSVs, RDLs and bond pads 150 have been shown in FIG. 2F, they are intended only for illustration, and the present invention is not limited to the particular numbers, locations and connections of them as shown, as modifications may be made thereto, as required.

For another first wafer (denoted as W11) to be bonded to the top wafer, before bonding, bond pads may also be formed on its front side or backside and then performing the hybrid bonding to connect bond pads 150 on the surface of the top wafer to corresponding bond pads on the surface of the first wafer W11, thereby establishing interconnections between the first wafer W11 and the top wafer.

This process of bonding the top wafer to the first wafer can be repeated to stack other first wafer(s) on the first wafer W11, forming the first wafer structure WS1, for example, as a “first wafer W10+first wafer W11+first wafer W12+first wafer W13+ . . . +first wafer WIn” stack (n is an integer greater than or equal to 1) as shown in FIG. 2G. As an example, the number of first wafers in the first wafer structure WS1 may be smaller than or equal to 5. For example, the first wafer structure WS1 may include one logic wafer (which may be the aforementioned first wafer W10, i.e., the top wafer) and four memory wafers.

When the first wafer structure includes at least two first wafers, alternatively, in step S1, the two or more first wafers may be first stacked and bonded, metal pad is formed on one side of the first wafer that is located at one end of the stacking direction, said side being away from other first wafer(s). For example, in one such embodiment (not shown), the formation of the first wafer structure may include: first providing the at least two first wafers, wherein one first wafer is the top wafer that is to be connected to the metal pad; then bonding the top wafer to a second carrier substrate; subsequently stacking another first wafer on the side of the top wafer away from the second carrier substrate; after the stacking is completed, removing the second carrier substrate; and then forming a top metal layer and a protective layer on the side of the top wafer away from the other first wafer. The top metal layer contains the metal pad. The top metal layer and the protective layer may be formed in the same way as described above in connection with FIGS. 2A to 2D. After that, the top wafer is bonded to a first carrier substrate through the protective layer. In this way, the same first wafer structure WS1 as is shown in FIG. 2G can also be obtained.

Referring to FIG. 1, in step 2, a second wafer structure is formed, which includes at least one second wafer.

Each second wafer in the second wafer structure may have a front side, on which electronic components are formed, and a backside opposite to the front side. The second wafer structure may include one, two or more second wafers.

When the second wafer structure includes a single second wafer, in step S2, the second wafer is acquired and prepared for bonding to the first wafer structure WS1. When the second wafer structure includes two or more second wafers, in step S2, the two or more second wafer are stacked and bonded in the same way as described above for the top wafer W10 and the first wafer W11. As an example, referring to FIG. 2H, the second wafer structure may be formed as described below.

First of all, a second wafer W20 including a second substrate 200 is acquired, and a fourth oxide layer 210 is deposited over a front side of the second wafer W20 and then planarized using a CMP process. The remaining portion of the fourth oxide layer 210 may have a thickness, for example, in the range of 5 kÅ to 15 kÅ.

The second wafer W20 is then bonded at the front side to a third carrier substrate 20 and the second substrate 200 in the second wafer W20 is thinned from the backside.

Subsequently, TSVs extending through the second substrate 200 and bond pads 220 connected to the respective TSVs are formed on the backside of the second wafer W20, and the backside of the second wafer W20 is bonded to a front side of another second wafer (denoted as the “second wafer W21”) using a bonding process.

This process of bonding the second wafer W20 and the second wafer W21 can be repeated multiple times to stack a desired number of second wafers on the third carrier substrate 20, thereby forming the second wafer structure WS2 as a “second wafer W20+second wafer W21+second wafer W22+second wafer W23+ . . . +second wafer W2n” stack (n is an integer greater than or equal to 1) as shown in FIG. 2H. As an example, the number of second wafers in the second wafer structure WS2 may be smaller than or equal to 5. For example, the second wafers in the second wafer structure WS2 may be memory wafers.

Referring to FIG. 1, in step S3, the first wafer structure WS1 and the second wafer structure WS2 are stacked and bonded, the second wafer structure WS2 is formed on the side of the first wafer structure WS1 away from the metal pad 131.

Referring to FIG. 2I, as an example, step S3 may include: thinning the substrate of the first wafer W1n in the first wafer structure WS1 away from the first carrier substrate 10 and forming TSVs extending through the first wafer W1n using a TSV process and bond pads 160 connected to the respective TSVs; and forming bond pads on a surface of the second wafer structure WS2, which are connected to interconnect structures within the second wafer. In this process, for example, as shown in FIG. 2H, the third carrier substrate 20 may be removed from the second wafer structure WS2, and bond pads 230 may be formed on the front side of the second wafer W20 in the second wafer structure WS2, which are connected to the interconnect structures within the second wafer W20. Afterwards, the surface of the first wafer structure WS1 with the bond pads 160 being formed thereon is bonded to the surface of the second wafer structure WS2 with the bond pads 160 being formed thereon.

Referring to FIG. 1, in step S4, openings are formed at one side of the first wafer structure WS1, exposing the metal pad 131.

For example, as shown in FIG. 2J, the first wafer structure WS1 and the second wafer structure WS2 are first flipped over, with the substrate of the second wafer W2n in the second wafer structure WS2 serving as a support, the first carrier substrate 10 is polished away using a CMP process, and the protective layer 140 is exposed. However, the present invention is not so limited. In some other embodiments, the first carrier substrate 10 may be removed otherwise. After the first carrier substrate 10 is removed, the third oxide layer 144 in the protective layer 140 is exposed, for example.

Subsequently, in order to expose the metal pad 131 covered by the protective layer 140, optionally, the protective layer 140 may be thinned to an appropriate thickness, for example, by performing a CMP process using the nitride layer 142 as a stop layer. The remaining portion of the protective layer 140 includes the first oxide layer 141, the nitride layer 142 and the second oxide layer 143 and has a planar top surface on the side away from the metal pad 131. After that, referring to FIG. 2K, portions of the protective layer 140 aligned with the metal pad 131 to be exposed are etched away, forming the openings 140a in which the metal pad 131 is exposed.

In the wafer stacking method discussed above, since it is unnecessary to fabricate the metal pad 131 and the protective layer 140 after the first wafer structure WS1 and the second wafer structure WS2 are stacked and bonded, it avoids introducing high temperature processes associated with forming metal pad 131 and protective layer 140, thereby preventing significant wafer warpage deformation caused by such thermal processing. Therefore, the risks of layer and/or film fracture and alarming of processing equipment in subsequent processes are reduced, and more wafers are allowed to be stacked by wafer-level stacking.

Embodiments of the present invention also provide a wafer stack structure obtainable according to the wafer stacking method discussed above.

Referring to FIGS. 2A to 2K, the wafer stack structure includes a first wafer structure WS1 and a second wafer structure WS2. The first wafer structure WS1 includes at least one first wafer (e.g., W10-Win of FIG. 2K), and the second wafer structure WS2 includes at least one second wafer (e.g., W20-W2n of FIG. 2K). Moreover, the first wafer structure WS1 includes metal pad 131 and a protective layer 140 on its side away from the second wafer structure WS2. The metal pad 131 is exposed from openings 140a in the protective layer 140. A surface of the protective layer 140 away from the second wafer structure WS2 extends in a single plane. As shown in FIG. 2K, the surface of the protective layer 140 away from the second wafer structure WS2 is higher than (or spaced apart from) the metal pad 131 and is flat.

As an example, the first wafer structure WS1 may include at least two first wafers stacked and bonded together, and/or the second wafer structure WS2 may include at least two second wafers stacked and bonded. For example, each first wafer in the first wafer structure WS1 may have a front side, on which electronic components are formed, and a backside opposite to the front side. The front sides of the first wafers may be all oriented in one direction, and the backsides thereof may be all oriented in the opposite direction. Alternatively, the front side of at least one of the first wafers may face the backside of another first wafer. For example, each second wafer in the second wafer structure WS2 may have a front side, on which electronic components are formed, and a backside opposite to the front side. The front sides of the second wafers may be all oriented in one direction, and the backsides thereof may be all oriented in the opposite direction. Alternatively, the front side of at least one of the second wafers may face the backside of another second wafer.

Referring to FIG. 2K, in the first wafer structure WS1, the metal pad 131 may be formed, for example, on a first wafer W10, referred to hereinafter as a top wafer. The top wafer includes first interconnect structures 110 formed on a first substrate 100 and a dielectric layer 120 and a top metal layer 130 formed on the first interconnect structures 110. There is a through hole 120a in the dielectric layer 120, and the top metal layer 130 extends through the through hole 120a and is connected to metal layer of the first interconnect structure 110. The top metal layer 130 contains the metal pad 131. Optionally, there may be 5 or fewer, such as 3-5, first wafers in the first wafer structure WS1. Additionally and/or alternatively, there may be 5 or fewer, such as 3-5, second wafers in the second wafer structure WS2. However, the present invention is not so limited. In some embodiments, the first wafer structure WS1 and the second wafer structure WS2 may each include more or fewer wafers.

Since the top metal layer 130 fills the through hole 120a, its top surface away from the first substrate 100 may have a height difference, and top surface of the top metal layer 130 may have a height difference from a top surface of the dielectric layer 120. In order to enable the protective layer 140 to have a flat surface away from the second wafer structure WS2 (which facilitates its bonding to a carrier), as an example, referring to FIG. 2K, the protective layer 140 may include first oxide layer 141, a nitride layer 142 and a second oxide layer 143. The first oxide layer 141 forms on the dielectric layer 120 and the top metal layer 130, with the metal pad 131 being exposed. The nitride layer 142 in turn forms on the first oxide layer 141, and the second oxide layer 143 forms on the nitride layer 142 and fills portions of the nitride layer 142 with a lower height occurring due to the aforementioned height difference. A top surface of the second oxide layer 143 away from the second wafer structure WS2 is flush with a top surface of the nitride layer 142 away from second wafer structure WS2. The openings 140a in the protective layer 140 extend through the nitride layer 142 and the first oxide layer 141.

In the wafer stack structure, the top metal layer 130 and the protective layer 140 may be formed before the first wafer structure WS1 and the second wafer structure WS2 are bonded together. During bonding, the first wafer structure WS1 is bonded to a carrier substrate through the protective layer 140, and the other side of the first wafer structure WS1 is bonded to the second wafer structure WS2. Since it is unnecessary to fabricate the top metal layer 130 and the protective layer 140 after the first wafer structure WS1 and the second wafer structure WS2 are stacked and bonded, this avoids performing high-temperature processing associated with forming of the top metal layer 130 and the protective layer 140 layer on the wafer stack structure, thereby preventing significant wafer warpage deformation of the stack structure that caused by such thermal processing. Therefore, the risks of layer and/or film fracture and alarming of processing equipment in subsequent processes are reduced, and more wafers are allowed to be stacked by wafer-level stacking.

It is noted that the embodiments disclosed herein are described in a progressive manner, with the description of each embodiment focusing on its differences from others. Cross-reference can be made between the embodiments for their common or similar features.

While the invention has been described above with reference to several preferred embodiments, it is not intended to be limited to these embodiments in any way. In light of the teachings hereinabove, any person of skill in the art may make various possible variations and changes to the disclosed embodiments without departing from the scope of the invention. Accordingly, any and all such simple variations, equivalent alternatives and modifications made to the foregoing embodiments without departing from the scope of the invention are intended to fall within the scope thereof.

What is claimed is:

1. A wafer stacking method, comprising:
forming a first wafer structure comprising at least one first wafer, wherein a side of the first wafer structure is pre-formed with at least one metal pad;
forming a second wafer structure comprising at least one second wafer;
stacking and bonding the first and second wafer structures, wherein the second wafer structure is bonded to a side of the first wafer structure that is away from the metal pad; and
forming at least one opening on a side of the first wafer structure, wherein the metal pad is exposed from the opening.

2. The wafer stacking method of claim 1, wherein forming the first wafer structure comprises:
taking one of the at least one first wafer in the first wafer structure as a top wafer, wherein the top wafer comprises at least one first interconnect structure formed on a first substrate and a dielectric layer formed on the first interconnect structure;
forming at least one through hole in the dielectric layer, wherein the through hole exposes a metal layer of the first interconnect structure; and
depositing a metal material into the through hole and onto a surface of the dielectric layer, and patterning the metal material, thereby forming a top metal layer connected to the first interconnect structure, wherein the top metal layer contains the metal pad.

3. The wafer stacking method of claim 2, wherein forming the first wafer structure further comprises:
after the top metal layer is formed, forming a first oxide layer and a nitride layer on a surface of the top wafer;
forming a second oxide layer covering the nitride layer, wherein an upper surface of the second oxide layer is higher than a surface of the nitride layer;
performing a planarization process using the nitride layer as a stop layer, wherein after the planarization process, a remaining portion of the second oxide layer covers a portion of the nitride layer and is flush with a remaining portion of the nitride layer that is exposed; and
forming a third oxide layer covering surfaces of exposed portions of the second oxide layer and the nitride layer, wherein the first oxide layer, the nitride layer and the second oxide layer make up a protective layer.

4. The wafer stacking method of claim 2, wherein the dielectric layer includes a silicon nitride layer and a silicon oxide layer that are stacked on the first interconnect structure.

5. The wafer stacking method of claim 2, wherein the top metal layer has a thickness in a range of 8 kÅ to 30 kÅ.

6. The wafer stacking method of claim 3, wherein the second oxide layer is a silicon oxide layer having a thickness in a range of 30 kÅ to 60 kÅ.

7. The wafer stacking method of claim 3, wherein the third oxide layer is a silicon oxide layer having a thickness in a range of 5 kÅ to 15 kÅ.

8. The wafer stacking method of claim 1, wherein the first wafer structure comprises at least two first wafers that are stacked and bonded, and/or wherein the second wafer structure comprises at least two second wafers that are stacked and bonded.

9. The wafer stacking method of claim 8, wherein forming the first wafer structure comprises:
providing the at least two first wafers, wherein one of the at least two first wafers is a top wafer on which the metal pad is to be formed;
forming a top metal layer and a protective layer covering the top metal layer on the top wafer, wherein the top metal layer contains the metal pad;
bonding the top wafer to a first carrier substrate through the protective layer; and
successively stacking the other first wafer(s) on a side of the top wafer away from the first carrier substrate.

10. The wafer stacking method of claim 8, wherein forming the first wafer structure comprises:
providing the at least two first wafers, wherein one of the at least two first wafers is a top wafer on which the metal pad is to be formed;
bonding the top wafer to a second carrier substrate;
successively stacking the other first wafer(s) on a side of the top wafer away from the second carrier substrate;
removing the second carrier substrate;
forming a top metal layer and a protective layer on a side of the top wafer away from the other first wafer(s), wherein the top metal layer contains the metal pad; and
bonding the top wafer to a first carrier substrate through the protective layer.

11. The wafer stacking method of claim 9, wherein stacking and bonding the first and second wafer structures comprises:
thinning a substrate of a first wafer in the first wafer structure on a side away from the first carrier substrate, forming through-silicon vias (TSVs) extending through the first wafer using a TSV process, and forming bond pads connected to the TSVs;
forming bond pads on a surface of the second wafer structure, wherein the bond pad is connected to the interconnect structure in the second wafer; and
bonding surface of the first wafer structure with the bond pad being formed thereon to surface of the second wafer structure with the bond pad being formed thereon.

12. The wafer stacking method of claim 10, wherein stacking and bonding the first and second wafer structures comprises:
thinning a substrate of a first wafer in the first wafer structure on a side away from the first carrier substrate, forming through-silicon vias (TSVs) extending through the first wafer using a TSV process, and forming bond pads connected to the TSVs;
forming bond pads on a surface of the second wafer structure, wherein the bond pad is connected to the interconnect structure in the second wafer; and
bonding surface of the first wafer structure with the bond pad being formed thereon to surface of the second wafer structure with the bond pad being formed thereon.

13. A wafer stack structure, comprising a first wafer structure and a second wafer structure that are stacked and bonded, wherein the first wafer structure comprises at least one first wafer, wherein the second wafer structure comprises at least one second wafer, wherein at least one metal pad and a protective layer covering the at least one metal pad are provided on a side of the first wafer structure that is away from the second wafer structure, wherein the metal pad is exposed from an opening in the protective layer, and wherein a surface of the protective layer away from the second wafer structure is within a single plane.

14. The wafer stack structure of claim 13, wherein the first wafer structure comprises a top wafer, wherein the top wafer comprises at least one first interconnect structure that is formed on a first substrate and a dielectric layer and a top metal layer that are formed on the first interconnect structure, wherein the dielectric layer is provided with at least one through hole, wherein the top metal layer extends through the through hole to connect with the metal layer of the first interconnect structure, wherein the top metal layer contains the metal pad.

15. The wafer stack structure of claim 14, wherein the protective layer comprises:
a first oxide layer formed on surfaces of the dielectric layer and the top metal layer, wherein the metal pad is exposed from the first oxide layer;
a nitride layer formed on a surface of the first oxide layer; and
a second oxide layer, formed on the nitride layer, wherein a top surface of the second oxide layer is flush with a top surface of the nitride layer.

16. The wafer stack structure of claim 15, wherein the first wafer structure comprises at least two first wafers that are stacked and bonded, and/or wherein the second wafer structure comprises at least two second wafers that are stacked and bonded.
